(19) United States
(12) Patent Application Publication
(10) Pub. No.: US 2015/0004432 A1
(43) Pub. Date: Jan. 1, 2015

(54) TITANIUM-NICKEL ALLOY THIN FILM, AND PREPARATION METHOD OF TITANIUM-NICKEL ALLOY THIN FILM USING MULTIPLE SPUTTERING METHOD

(71) Applicants: Seong Woong Kim, Changwon-si (KR); Jong Taek Yeom, Gimhae-si (KR); Jae Keun Hong, Changwon-si (KR); Jeoung Han Kim, Changwon-si (KR); Chan Hee Park, Changwon-si (KR)

(72) Inventors: Seong Woong Kim, Changwon-si (KR); Jong Taek Yeom, Gimhae-si (KR); Jae Keun Hong, Changwon-si (KR); Jeoung Han Kim, Changwon-si (KR); Chan Hee Park, Changwon-si (KR)

(73) Assignee: KOREA INSTITUTE OF MACHINERY & MATERIALS, Daejeon-si (KR)

(21) Appl. No.: 14/354,818

(22) PCT Filed: Aug. 13, 2012
(86) PCT No.: PCT/KR2012/006459

§ 371 Date: Aug. 18, 2014

(30) Foreign Application Priority Data
Oct. 28, 2011 (KR) 10-2011-0111184
Jun. 28, 2012 (KR) 10-2012-0069517

(51) Int. Cl. C23C 14/34; B32B 15/01; C22C 19/03; C23C 14/14

(52) U.S. Cl. CPC C23C 14/3464; C23C 14/14; B32B 15/01; C22C 19/03
USPC 428/641; 204/192.1; 428/469; 420/441

(57) ABSTRACT

In a Ti—Ni alloy thin film, Ti and Ni are mixed and deposited on a base material by putting a Ti target and an Ni target at a predetermined distance from each other in a co-sputtering apparatus and simultaneously sputtering the targets by applying different voltages. A method of fabricating a Ti—Ni alloy thin film using co-sputtering includes a target preparing step that prepares a Ti target, a Ni target and a base material, a target disposing step that puts the Ti target and the Ni target at a predetermined distance from each other in a co-sputtering apparatus, an apparatus setting step that sets work conditions of the co-sputtering apparatus, and a thin film depositing step that forms a Ti—Ni alloy thin film with Ti and Ni mixed on the base material by operating the co-sputtering apparatus.

### TECHNICAL FIELD

The present invention relates to a Ti—Ni alloy thin film and a fabrication method of the Ti—Ni alloy thin film using co-sputtering, and more particularly to a Ti—Ni alloy thin film that is fabricated by putting a titanium target and a nickel target that are separately prepared into a chamber, at a predetermined distance from each other, and simultaneously sputtering them under different conditions, and a method of fabricating the Ti—Ni alloy thin film using co-sputtering.

The present invention relates to a Ti—Ni alloy thin film and a method of fabricating the Ti—Ni alloy thin film using co-sputtering, and more particularly to a Ti—Ni alloy thin film that has a shape memory ability by putting a Ti target and an Ni target that are separately prepared into a chamber, at a predetermined distance from each other, and forming an alloy thin film on a base material by simultaneously sputtering them under different conditions, and performing heat treatment and solution treatment, and a method of fabricating the Ti—Ni alloy thin film using co-sputtering.

### BACKGROUND

A Ti—Ni-based alloy is not only used for practical shape memory alloys having high strength and ductility, but also is a very attractive functional material because of specific physical properties such as pre-transformation due to various martensite transformations.

A shape memory alloy is a material that can return to the original shape after heating. The shape memory alloy is especially useful for vehicles, the aerospace industry, thin films, robotics, and the medical science because of the specific characteristics.

Accordingly, Ni—Ti alloys are fabricated in various methods. For example, a technology of forming a chromium layer and a polyimide layer on a base material of SiO₂ and forming a Ni—Ti layer on a polyimide layer using sputtering is disclosed in S. Miyazaki and A. Ishida, MSE A, 273(1999) 106.

However, the polyimide is removed by KOH and the Cr layer is removed by etching to obtain the Ni—Ti layer from the technology, such that there is a problem in that the fabricating process is complicated.

Further, the Ni—Ti alloy is low in purity, generally has a high work hardening rate, and many in-process heat treatments are required to ensure again ductility.

The complicated fabricating process causes contaminants to remain and the existence of contaminants may influence the mechanical properties and biocompatibility of the material.

Accordingly, various deposition technologies have been developed to fabricate a high-purity shape memory alloy.

In those technologies, E-beam evaporation that does not use plasma has a high-speed deposition ability, but the density of a deposited thin film is low, so the quality of high performance cannot be ensured.

In order to improve this problem, diode type sputtering deposition using plasma to obtain high quality even though the speed is low has been introduced, but this method also has a low deposition speed and a low process range, such that magnetron sputtering that has a little wide process range and an increased deposition speed by using a magnetic field has been developed and proposed.

This sputtering also has a problem in that the target using efficiency is low and a fine arc is generated by contamination of the target surface, such that double magnetron sputtering and cylindrical magnetron sputtering obtained by improving the sputtering have been developed.

Further, in order to increase the quality of the deposited thin film, a sputtering technology using inductively coupled plasma and a deposition technology using high-power impulse magnetron sputtering (HIPIMS) using high-current impulse power have been developed recently.

A patent about a high-density plasma source for depositing ionized metal have been published in Korean Patent Publication No. 2001-0021283. In this document, a technology about magnetron suitable for low-pressure plasma sputtering or continuous magnetic sputtering which has a reduced area, but the maximum target coverage has been disclosed.

Further, a patent about a magnetron sputtering system for a large-area substrate published in Korean Patent Publication No. 2007-0008369 has been registered, in which an apparatus and a method for processing the surface of a substrate in a physical vapor deposition chamber having an increased anode surface to improve deposition uniformity on a substrate generally having a large area have been disclosed.

However, those published patents have a defect that the deposition speed and deposition rate are decreased, the using efficiency of an object material that is the target is low, and efficiency is decreased by local heat.

### SUMMARY

In order to solve the problems of the related art, an object of the present invention is to provide a Ti—Ni alloy thin film and a method of fabricating the Ti—Ni alloy thin film using co-sputtering, and more particularly to a Ti—Ni alloy thin film that is fabricated by putting a Ti target and an Ni target that are separately prepared into a chamber, at a predetermined distance from each other, and simultaneously sputtering them under different conditions, and a method of fabricating the Ti—Ni alloy thin film using co-sputtering.

Another object of the present invention is to provide a Ti—Ni alloy thin film that is fabricated by putting a Ti target and an Ni target that are separately prepared into a chamber, at a predetermined distance from each other, and simultaneously sputtering them under different conditions, and a method of fabricating the Ti—Ni alloy thin film using co-sputtering.

Another object of the present invention is to provide a Ti—Ni alloy thin film that can be fabricated by a simpler fabricating process by selecting monocrystal NaCl as a base material and a method of fabricating the Ti—Ni alloy thin film using co-sputtering.

### Technical Solution

In a Ti—Ni alloy thin film according to the present invention, Ti and Ni are mixed and deposited on a base material by putting a Ti target and an Ni target at a predetermined distance from each other in a co-sputtering apparatus and simultaneously sputtering the targets by applying different voltages.

A Ti—Ni alloy thin film is formed by Ti and Ni mixed and deposited on a base material by putting a Ti target and an Ni target at a predetermined distance from each other in a co-sputtering apparatus and simultaneously sputtering the targets by applying different voltages, wherein the Ti—Ni alloy thin film is crystallized by annealing at 500° C. or more for 30 minutes or more.

The base material is made of any one of Si wafer, monocrystal NaCl, and polycrystalline NaCl.

The Ti of 43.2 to 44.9 wt % to the entire weight of the Ti—Ni alloy thin film is included.

A voltage 3.2 to 3.4 times higher than that of the Ni target is applied to the Ti target.

The Ti—Ni alloy thin film includes B₂ Rhombohedral (Ti₃Ni₄) in rapid cooling after annealing.

A method of fabricating a Ti—Ni alloy thin film using co-sputtering according to an embodiment of the present invention includes: a target preparing step that prepares a Ti target, a Ni target, and a base material; a target disposing step that puts the Ti target and the Ni target at a predetermined distance from each other in a co-sputtering apparatus; an apparatus setting step that sets work conditions of the co-sputtering apparatus; and a thin film depositing step that forms a Ti—Ni alloy thin film with Ti and Ni mixed on the base material by operating the co-sputtering apparatus.

A method of fabricating a Ti—Ni alloy thin film using co-sputtering according to another embodiment of the present invention includes: a target preparing step that prepares a Ti target, a Ni target, and a base material; a target disposing step that puts the Ti target and the Ni target at a predetermined distance from each other in a co-sputtering apparatus; an apparatus setting step that sets work conditions of the co-sputtering apparatus; a thin film depositing step that forms a Ti—Ni alloy thin film with Ti and Ni mixed on the base material by operating the co-sputtering apparatus; a crystallizing step that crystallizes the Ti—Ni alloy thin film by annealing the Ti—Ni alloy thin film at a temperature of 500° C. or more for 30 minutes or more; and a function applying step that forms B₂ and Rhombohedral (Ti₃Ni₄) phases by rapidly cooling the crystallized Ti—Ni alloy thin film.

In the target preparing step, the base material is selected from any one of Si wafer, monocrystal NaCl, and polycrystalline NaCl.

After the thin film depositing step, a thin film separating step that removes the base material is performed when the base material is made of monocrystal NaCl.

In the apparatus setting step, a voltage 3.2 to 3.4 times higher than that of the Ni target is applied to the Ti target.

In the thin film depositing step, Ti has an atomic ratio of 48.53 to 54.33 to the entire Ti—Ni alloy thin film.

### Advantageous Effects

The present invention fabricates a Ti—Ni alloy thin film by putting a Ti target and an Ni target separately prepared at a predetermined distance from each other in the chamber and then simultaneously sputtering them under different conditions.

Accordingly, there is the advantage that the characteristics are improved, because the composition ratio of Ti and Ni can be set to be optimal.

Further, NaCl can be selectively used as a base material in the present invention.

Further, there is the advantage that the fabricating process of Ti—Ni can be simplified and the fabricating cost can be reduced.

In addition, there is the advantage that the structure is crystallized by annealing and a shape memory function can be given by rapid cooling.

### BRIEF DESCRIPTION OF THE DRAWINGS

FIG. 1 is a schematic view illustrating the configuration of a Ti—Ni alloy thin film according to the present invention.

FIG. 2 is a view schematically illustrating the configuration of a sputtering apparatus for fabricating a Ti—Ni alloy thin film according to the present invention.

FIG. 3 is an actual picture of a Ti—Ni alloy thin film according to the present invention that has been deposited on a base material.

FIG. 4 is an actual picture of a Ti—Ni alloy thin film according to the present invention that has been separated from a base material.

FIG. 5 is a flowchart illustrating a method of fabricating a Ti—Ni alloy thin film using co-sputtering according to the present invention.

FIGS. 6a to 6e are tables the ratio of Ti and Ni in a Ti—Ni alloy thin film when voltage applied to a titanium target is maintained and voltage applied to a nickel target is changed in a thin film deposition step of the method of fabricating a Ti—Ni alloy thin film using co-sputtering according to the present invention.

FIG. 7 is an SEM picture illustrating the cross-section of #1 in a Ti—Ni alloy thin film fabricated under the test conditions of FIG. 6d.

FIG. 8 is an SEM picture illustrating the cross-section of #2 in a Ti—Ni alloy thin film fabricated under the test conditions of FIG. 6a.

FIG. 9 is an TEM picture illustrating the surface of #1 in a Ti—Ni alloy thin film fabricated under the test conditions of FIG. 6e.

FIG. 10 is a flowchart illustrating another embodiment of a method of fabricating a Ti—Ni alloy thin film using co-sputtering according to the present invention.

FIG. 11 is a table illustrating the conditions of the steps in a method of fabricating a Ti—Ni alloy thin film using co-sputtering according to the present invention and the composition of the Ti—Ni alloy thin film.

FIG. 12 is a picture illustrating the surface and an E-ray diffraction pattern of a thin film fabricated in a thin film deposition step that is a step of the method of fabricating a Ti—Ni alloy thin film using co-sputtering according to the present invention.

FIG. 13 is a picture illustrating the surface and an E-ray diffraction pattern of a comparative example 1.

FIG. 14 is a picture illustrating the surface and an E-ray diffraction pattern of a comparative example 2.

FIG. 15 is a picture illustrating the surface and an E-ray diffraction pattern of a preferred embodiment 6 in the method of fabricating a Ti—Ni alloy thin film using co-sputtering.

FIG. 16 is an actual picture of a preferred embodiment 8 in the method of fabricating a Ti—Ni alloy thin film using co-sputtering.

FIG. 17 is an actual picture of a preferred embodiment 8 in the method of fabricating a Ti—Ni alloy thin film using co-sputtering.

FIG. 18 is an actual picture of a preferred embodiment 9 in the method of fabricating a Ti—Ni alloy thin film using co-sputtering.

FIG. 19 is a table illustrating a thermal flow result according to a temperature change in a preferred embodiment 60 in the method of fabricating a Ti—Ni alloy thin film using co-sputtering.

FIG. 20 is an XRD graph of a Ti—Ni alloy thin film when a function applying step in the method of fabricating a Ti—Ni alloy thin film using co-sputtering.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

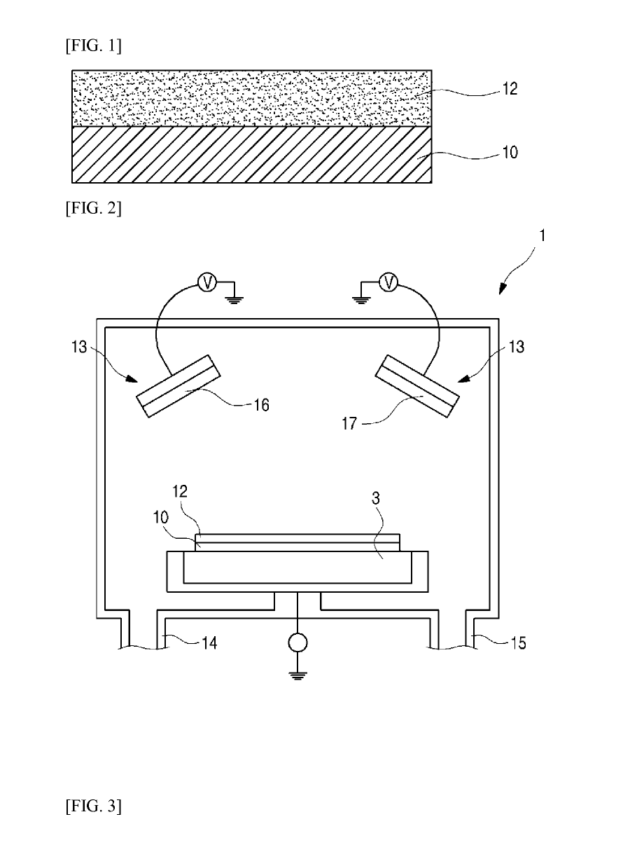

Hereinafter, the configuration of a Ti—Ni alloy thin film according to the present invention is described with reference to FIG. 1 in the accompanying drawings.

FIG. 1 is a schematic view illustrating the configuration of a Ti—Ni alloy thin film according to the present invention.

However, the possibility of implementing the spirit of the present invention is not limited to the following embodiments and those skilled in the art can easily propose other embodiments included in the range of the same spirit and they are construed as being included in the spirit of the present invention.

Further, the terminologies used in the specification and claims are selected for the convenience of description and should be appropriately construed as meanings following the spirit of the present invention in understanding of the technical matters of the present invention.

As illustrated in the figure, a Ti—Ni alloy thin film according to the present invention (hereafter, referred to as a ‘alloy thin film 12’) is formed by depositing on the outer side of a base material 10, using co-sputtering, in which Ti and Ni keep mixed.

The base material 10 is made of any one of an Si wafer or monocrystal NaCl. When the base material 10 is made of monocrystal NaCl, it can be selectively removed and only the alloy thin film 12 remain, and the base material 10 and the alloy tin film 12 may be attached in fabricating.

FIG. 2 is a schematic view illustrating the configuration of a co-sputtering apparatus for fabricating the alloy thin film 12 and the apparatus includes a chamber 2 having a space for sputtering therein, a sputter gun 13 in which an electrode 3 where the base material 10 is seated, a Ti target 16, and a Ni target 17 are separated, a gas supply portion 14 for supplying an inert gas into the chamber, and a gas discharge portion 15 for discharging a gas in the chamber to the outside.

A plurality of sputter guns 13 is provided and have targets made of different materials, and in the embodiment of the present invention, the Ti target 16 and the Ni target 17 are provided.

The chamber is filled with argon (Ar) gas supplied through the gas supply portion and the Ti—Ni alloy thin film 12 can be fabricated by being maintained for 750 seconds at a room temperature (25° C.).

In the entire Ti—Ni alloy thin film 12, Ti has an atomic ratio of 48.53 to 54.33.

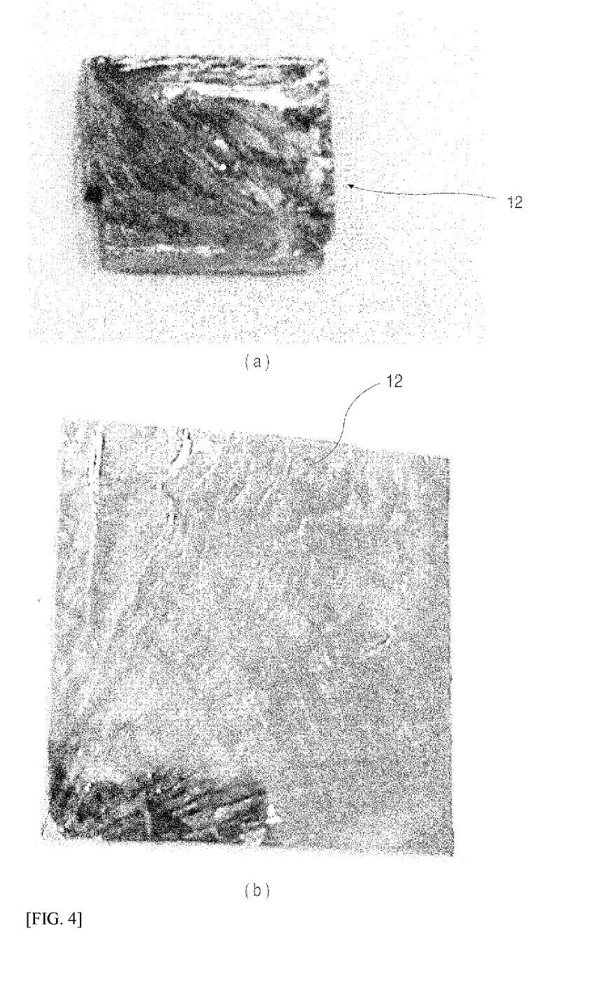

The Ti—Ni alloy thin film 12 fabricated in accordance with an embodiment of the present invention is as those illustrated in FIGS. 3 and 4.

That is, FIG. 3 is an actual picture of a Ti—Ni alloy thin film according to the present invention that has been deposited on a base material and FIG. 4 is an actual picture of a Ti—Ni alloy thin film according to the present invention that has been separated from a base material.

In detail, (a) of FIG. 3 exhibits one with monocrystal NaCl selected as the base material 10 and (b) of FIG. 3 is one with polycrystalline NaCl selected as the base material 10.

FIG. 4 is an actual picture of the Ti—Ni alloy thin film 12 separated from the base material 10 from (b) of FIG. 3.

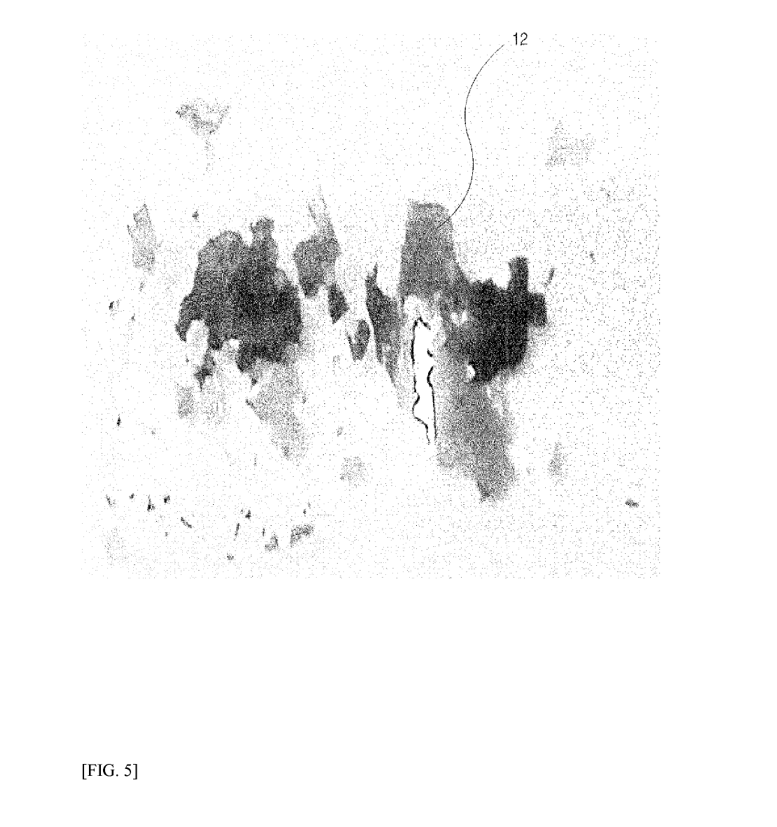

A method of fabricating a Ti—Ni alloy thin film of a first embodiment according to the present invention is described with reference to FIG. 5 in the accompanying drawings.

As in FIG. 5, the method of fabricating a Ti—Ni alloy thin film includes: a target preparing step S100 that prepares the Ti target 16, the Ni target 17, and the base 10; a target disposing step S200 that disposing the Ti target 16 and the Ni target 17 at a predetermined distance from each other in the co-sputtering apparatus 1; an apparatus setting step S300 that sets the work conditions of the co-sputtering apparatus 1; and a thin film depositing step S400 that forms the Ti—Ni alloy thin film 12 with Ti and Ni mixed on the base material 10 by operating the co-sputtering apparatus 1.

In the target preparing step S100, targets were separately prepared as the Ti target 16 and the Ni target 17 in the embodiment of the present invention and a base material 10 made of any one of an Si wafer or monocrystal NaCl was prepared.

When the base material 10 and the targets are prepared, as described above, the target disposing step S200 is performed. The target disposing step S200 is a step in which the Ti target 16 and the Ni target 17 are disposed at a predetermined distance from each other in the chamber, as in FIG. 2.

The apparatus setting step S300 is performed after the target disposing step S200. The apparatus setting step S300 is a process of setting conditions for fabricating the Ti—Ni alloy thin film 12 with the optimum atomic ratio on the co-sputtering apparatus 1 on the basis of the test results to be described below.

That is, the apparatus is set such that voltage 3.2 to 3.4 times higher than that of the Ni target 17 is applied to the Ti target 16.

In more detail, the apparatus is set such that voltage of 5000 W is applied to the Ti target 16 and voltage of 1500 to 1550 W is applied to the Ni target 17.

The thin film depositing step S400 is a process of forming the Ti—Ni alloy thin film 12 on the base material 10 by performing co-sputtering, and when the thin film depositing step S400 is finished, Ti has an atomic ratio of 48.53 to 54.33 to the whole atoms of the Ti—Ni alloy thin film 12.

When the base material 10 is made of monocrystal NaCl, the thin film separating step S500 can be performed.

The thin film separating step S500 is a process of separating the Ti—Ni alloy thin film 12 from the base material 10 by removing the base material 10 made of NaCl and the thin film separating step S500 can be performed only by a simple process that dissolves water without the complicated process of the related art for removing the base material 10.

The Ti—Ni alloy thin film 12 fabricated in accordance with the process has the state illustrated in FIG. 1.

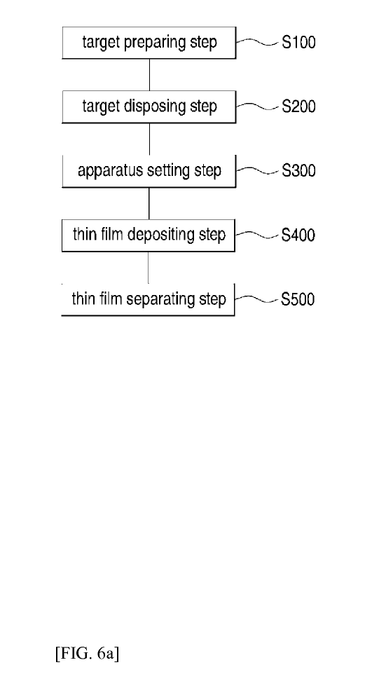

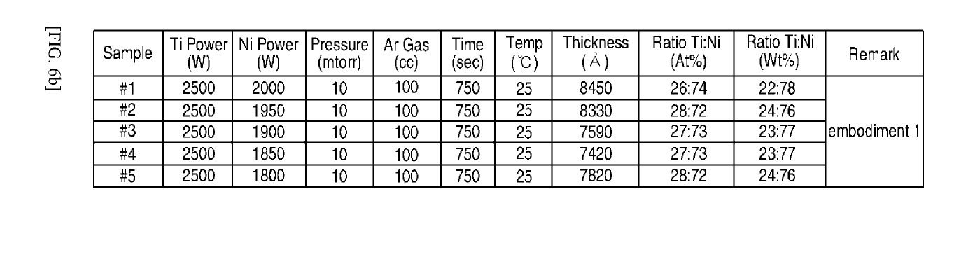

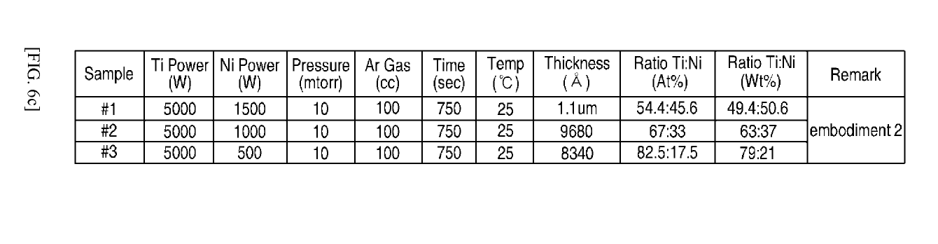

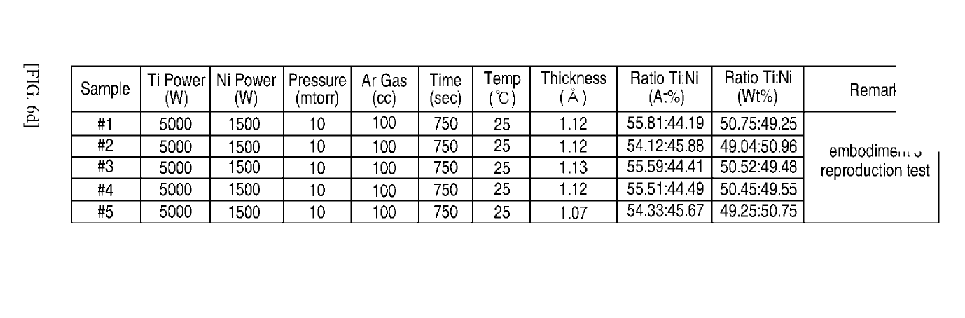

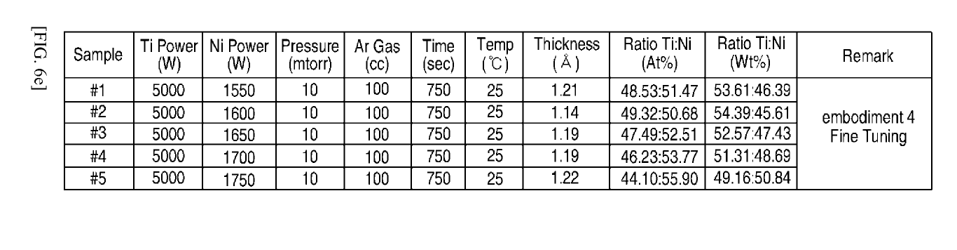

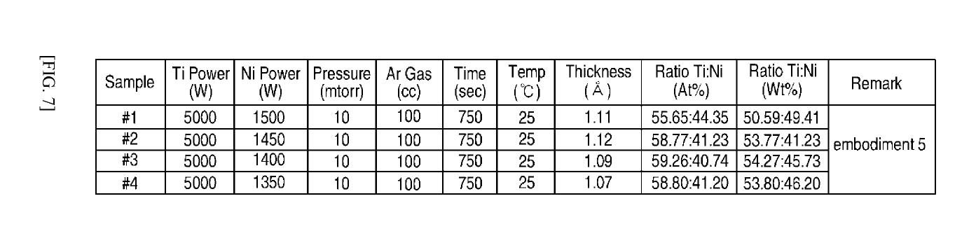

An embodiment of a method of fabricating a Ti—Ni alloy thin film using co-sputtering according to the present invention is described with reference to FIGS. 6a to 6e.

FIGS. 6a to 6e exhibit tables listing the ratios of Ti and Ni in a Ti—Ni alloy thin film 12 when invention the voltage applied to the Ti target 16 is maintained and the voltage applied to the Ni target 17 is changed in the thin film depositing step S400 of the method of fabricating a Ti—Ni alloy thin film using co-sputtering according to the present.

As in the figures, in the embodiment of the present invention, the sputtering temperature, the performing time, the supply amount of argon gas, and the pressure were the same and the voltages applied to the Ti target 16 and the Ni target 17 were different.

The internal space of the chamber has an environment maintaining the vacuum degree of about maximum 10⁻³ to 10⁻⁷ torr. This is for preventing undesired gases (for example, oxygen and nitrogen) in the air from producing an unnecessary compound while the Ti—Ni alloy thin film 12 is actually deposited, by being ionized when plasma is produced.

Plasma is produced in the chamber by injecting an inert gas such as argon gas, in which the process vacuum degree may reach up to 0.01 mTorr.

In the embodiment of the present invention, the test was conducted with the process vacuum degree maintained within the range of about 0.6 mTorr to 3 mTorr.

Further, the high-density plasma has density of about 3×10¹³ cm⁻³.

That is, co-sputtering was performed with voltage of 2500 W applied to the Ti target 16 and voltage for the Ni target 17 changed within the range of 1800 to 2000 W in the embodiment 1.

Co-sputtering was performed with voltage of 5000 W applied to the Ti target 16 and voltage for the Ni target 17 changed within the range of 500 to 1500 W in the embodiment 2.

A reproducing test of the second embodiment was performed with voltage of 5000 W applied to the Ti target 16 and voltage of 1500 W applied to the Ni target 17 in the embodiment 3.

Co-sputtering was performed with voltage of 5000 W applied to the Ti target 16 and voltage for the Ni target 17 changed within the range of 1550 to 1750 W in the embodiment 4.

Co-sputtering was performed with voltage of 50000 W applied to the Ti target 16 and voltage for the Ni target 17 changed within the range of 1350 to 1500 W in the embodiment 5.

As a result, it can be seen that the optimum weight ratio was illustrated when the atomic ratio Ti is 48.53 to 54.53 to the entire Ti—Ni alloy thin film 12 in #5 of the embodiment 3 and #1 of the embodiment 4.

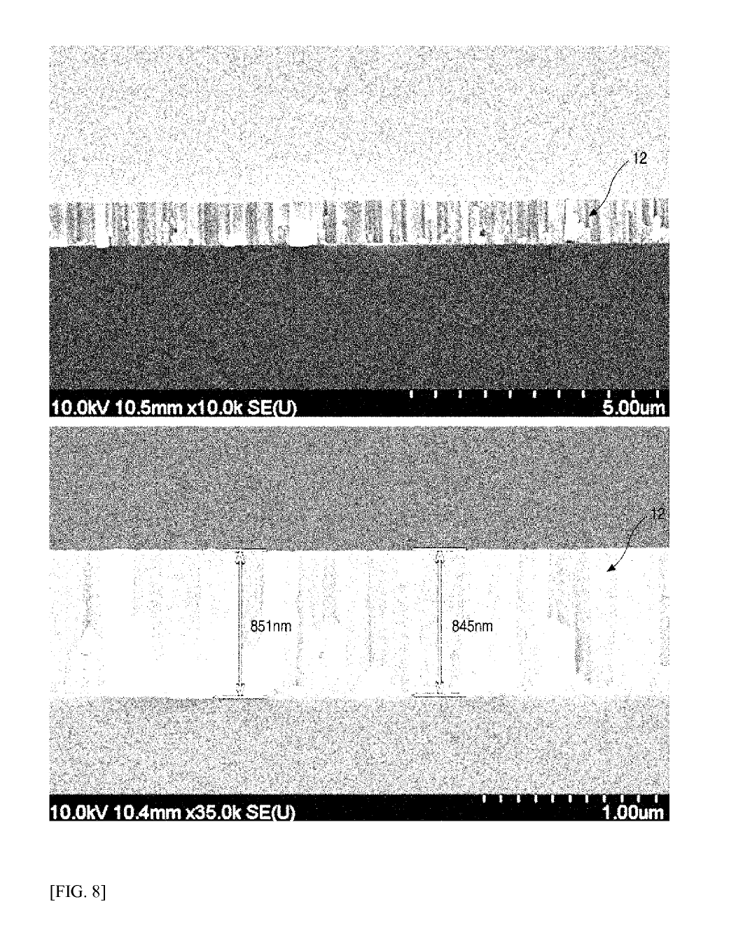

FIG. 7 is an SEM picture illustrating the cross-section of #1 in a Ti—Ni alloy thin film 12 fabricated under the test conditions of FIG. 6d and FIG. 8 is an SEM picture illustrating the cross-section of #2 in a Ti—Ni alloy thin film fabricated under the test conditions of FIG. 6a.

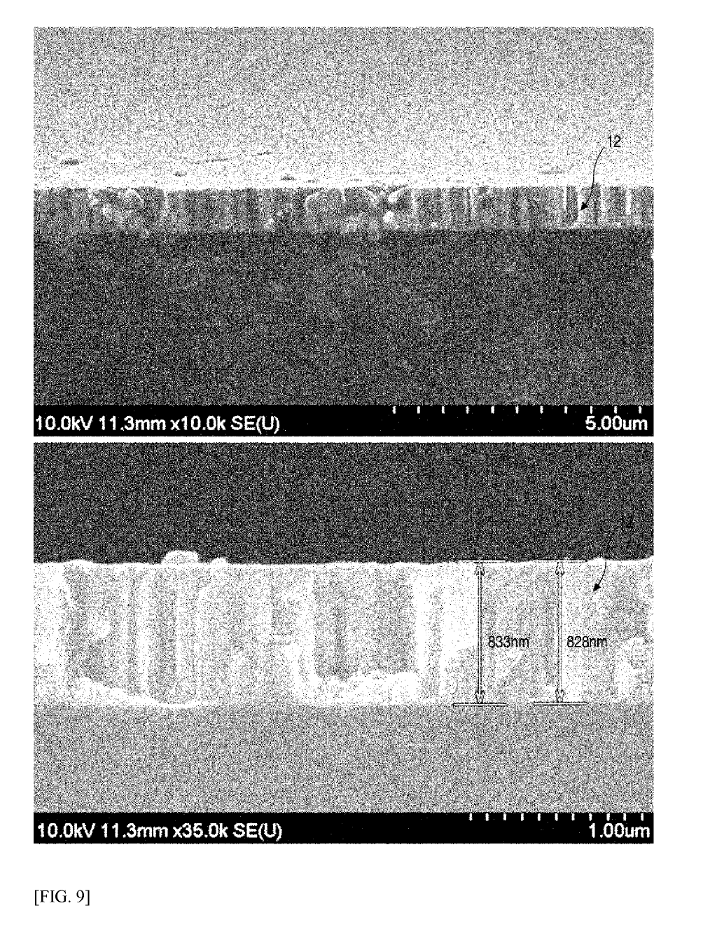

Further, FIG. 9 is a TEM picture illustrating the surface of #1 in a Ti—Ni alloy thin film 12 fabricated under the test conditions of FIG. 6e, in which it can be seen that there are repeated similar microstructures.

The Ti—Ni thin film 12 fabricated in accordance with the test result is attached to the base material 10 made of monocrystal NaCl, as in FIG. 3.

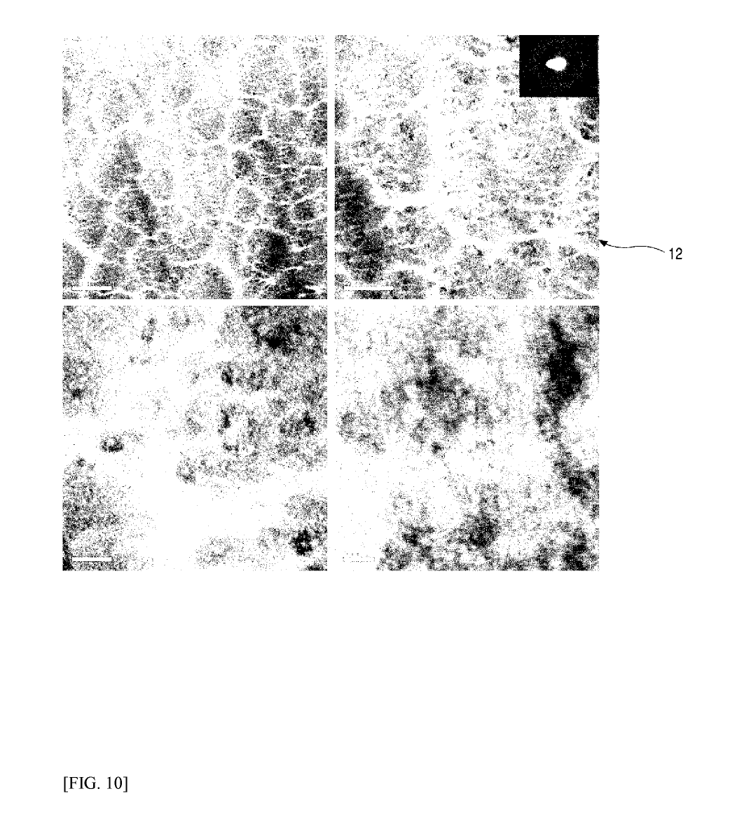

The Ti—Ni alloy thin film according to the present invention may be selected as another example, as in FIG. 10.

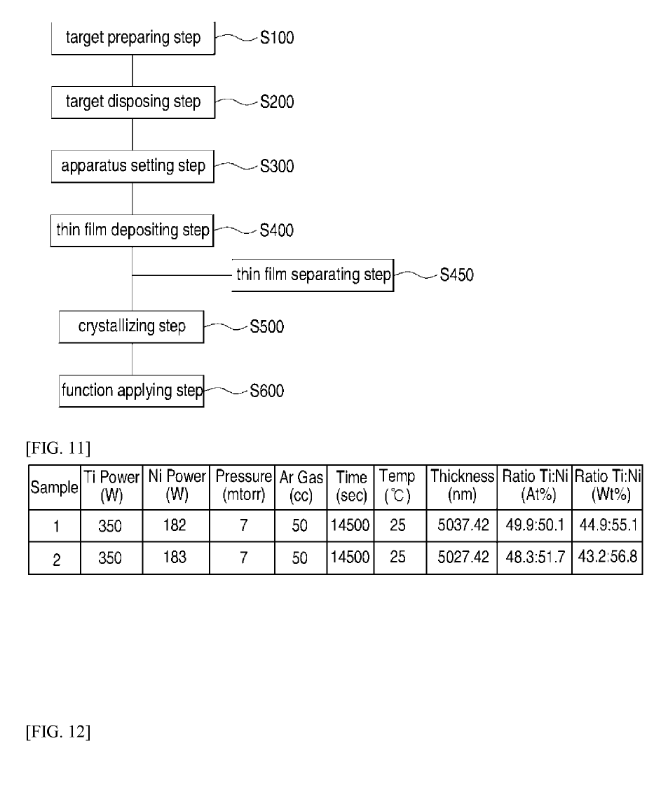

The method of fabricating the Ti—Ni alloy thin film is described with reference to FIGS. 10 and 11 in the accompanying drawings.

FIG. 10 is a flowchart illustrating another embodiment of a method of fabricating a Ti—Ni alloy thin film using co-sputtering according to the present invention and FIG. 11 is a table listing the conditions of the steps in a method of fabricating a Ti—Ni alloy thin film using co-sputtering according to the present invention and the composition of the Ti—Ni alloy thin film.

As in FIG. 10, the method of fabricating a Ti—Ni alloy thin film includes: a target preparing step S100 that prepares the Ti target 16, the Ni target 17, and the base 10; a target disposing step S200 that disposing the Ti target 16 and the Ni target 17 at a predetermined distance from each other in the co-sputtering apparatus 1; an apparatus setting step S300 that sets the work conditions of the co-sputtering apparatus 1; a thin film depositing step S400 that forms the Ti—Ni alloy thin film 12 with Ti and Ni mixed on the base material 10 by operating the co-sputtering apparatus 1; a crystallizing step S500 that crystallizes the Ti—Ni alloy thin film 12 by annealing it at a temperature of 500° C. or more for 30 minutes or more; and a function applying step S600 that forms B₂ and Rhombohedral (Ti₃Ni₄) phases by rapidly cooling the crystallized Ti—Ni alloy thin film 12.

In the target preparing step S100, targets were separately prepared as the Ti target 16 and the Ni target 17 in the embodiment of the present invention and monocrystal NaCl was prepared as the base material 10.

When the base material 10 and the targets are prepared, as described above, the target disposing step S200 is performed. The target disposing step S200 is a step in which the Ti target 16 and the Ni target 17 are disposed at a predetermined distance from each other in the chamber, as in FIG. 2.

The apparatus setting step S300 is performed after the target disposing step S200. The apparatus setting step S300 is a process of setting conditions for fabricating the Ti—Ni alloy thin film 12 with the optimum atomic ratio on the co-sputtering apparatus 1 on the basis of the test results to be described below.

That is, a voltage higher than that of the Ni target 17 is applied to the Ti target 16, as in FIG. 11.

In more detail, the apparatus is set such that voltage of 350 W is applied to the Ti target 16 and voltage of 182 to 183 W is applied to the Ni target 17.

The thin film depositing step S400 is a process of forming the Ti—Ni alloy thin film 12 on the base material 10 by performing co-sputtering, and when the thin film depositing step S400 is finished, Ti has a wt % of 43.2 to 44.9 to the entire weight of the Ti—Ni alloy thin film 12.

The thin film separating step S450 is performed after the thin film depositing step S400.

The thin film separating step S500 is a process of separating the Ti—Ni alloy thin film 12 from the base material 10 by removing the base material 10 made of NaCl and the thin film separating step S500 can be performed only by a simple process that dissolves water without the complicated process of the related art for removing the base material 10.

The crystallizing step S500 is performed after the thin film separating step S450. The crystallizing step S500 is a process of crystallizing the Ti—Ni alloy thin film by annealing it at a temperature of 500° C. or more for 30 minutes or more.

The function applying step S600 is performed after the crystallizing step S500. The function applying step S600, which is a process of applying required physical properties or functions by changing the structure phase of the Ti—Ni alloy thin film 12, is a process of providing a shape memory function by forming B₂ and Rhombohedral (Ti₃Ni₄) phases therein by rapidly cooling the crystallized Ti—Ni alloy thin film 12 in the embodiment of the present invention.

The Ti—Ni alloy thin film 12 fabricated in accordance with the process has the state illustrated in FIG. 1.

The surface state and an E-ray diffraction pattern of the Ti—Ni alloy thin film 12 according to a change in condition of the crystallizing step S500 are compared with reference to FIGS. 12 to 15 in the accompanying drawings.

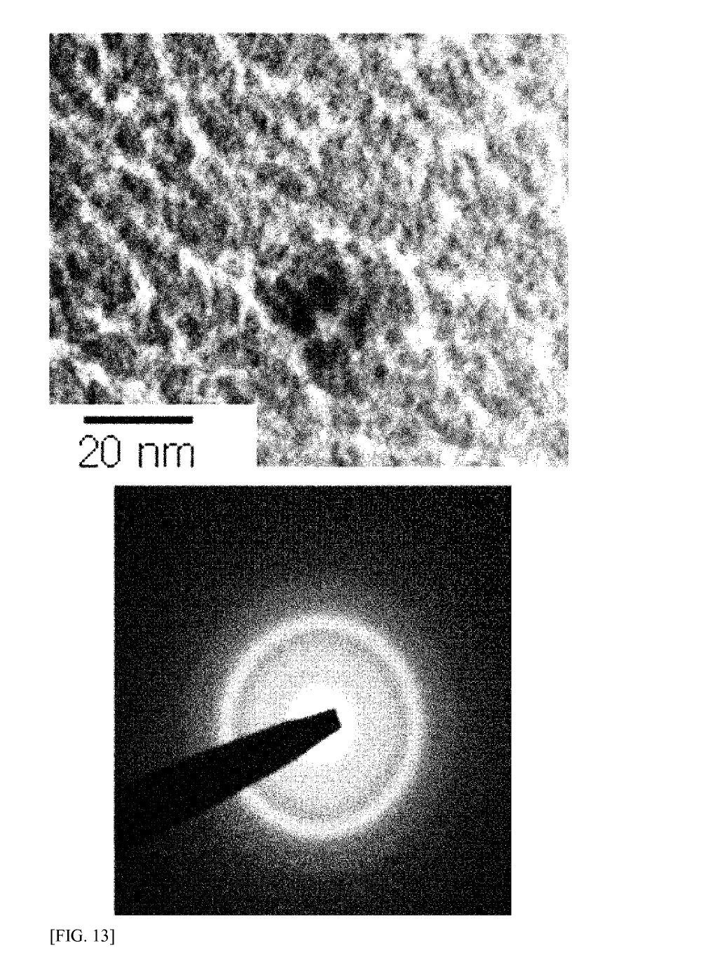

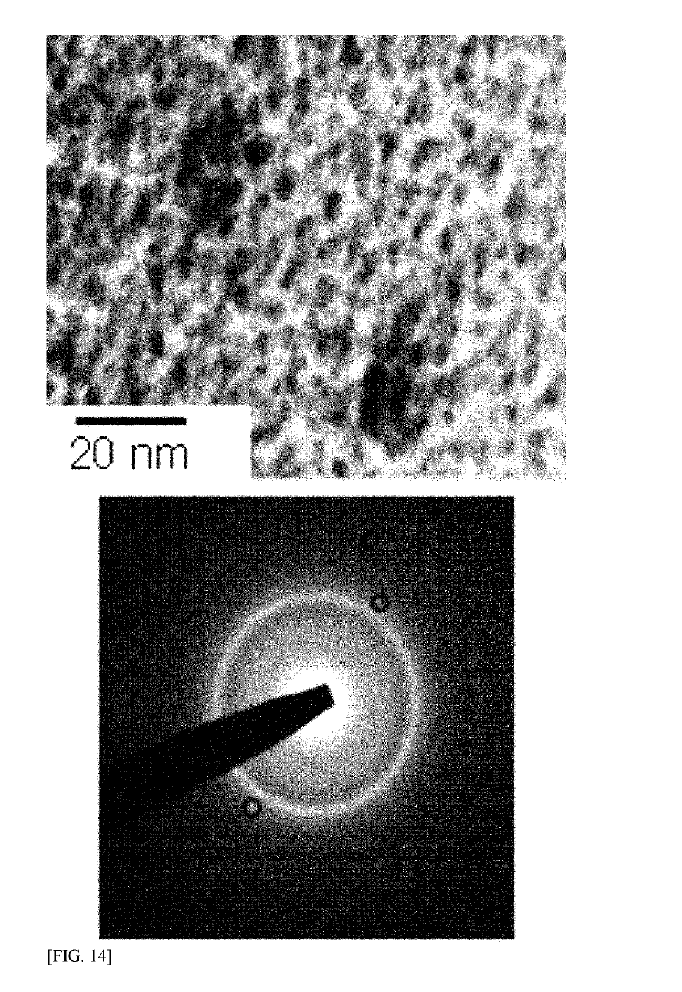

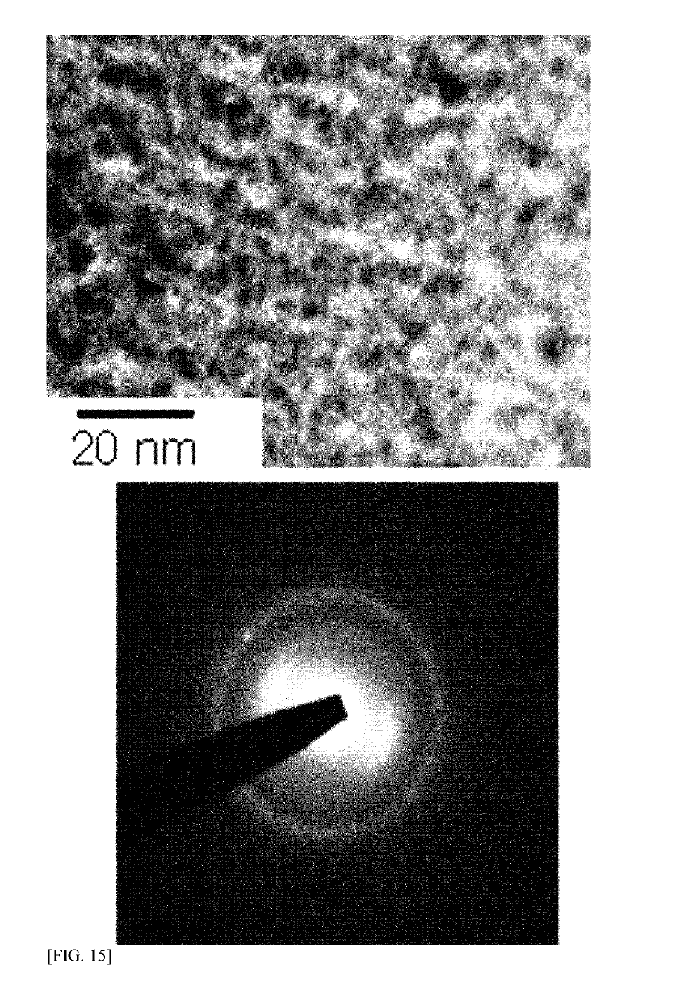

FIG. 12 is a picture illustrating the surface and an E-ray diffraction pattern of a thin film fabricated in a thin film deposition step that is a step of the method of fabricating a Ti—Ni alloy thin film using co-sputtering according to the present invention, FIGS. 13 and 14 are pictures illustrating the surface and an E-ray diffraction pattern of a comparative example 1 and a second comparative example 2, and FIG. 15 is a picture illustrating the surface and an E-ray diffraction pattern of a preferred embodiment 6 in the method of fabricating a Ti—Ni alloy thin film using co-sputtering.

As in the figures, in the embodiment of the present invention, the sputtering temperature, the performing time, the supply amount of argon gas, and the pressure were the same and the voltages applied to the Ti target 16 and the Ni target 17 were different.

The internal space of the chamber has an environment maintaining the degree of vacuum of about maximum 10⁻³ to 10⁻⁷ torr. This is for preventing undesired gases (for example, oxygen and nitrogen) in the air from producing an unnecessary compound while the Ti—Ni alloy thin film 12 is actually deposited, by being ionized when plasma is produced.

Plasma is produced in the chamber by injecting an inert gas such as argon gas, in which the process vacuum degree may reach up to 0.01 mTorr.

In the embodiment of the present invention, the test was conducted with the internal pressure of the chamber maintained at 7 mTorr under an argon atmosphere.

Co-sputtering was performed with voltage of 350 W applied to the Ti target 16 and voltage for the Ni target 17 changed within the range of 182 to 183 W (see FIG. 11).

First, as in FIG. 12, the Ti—Ni alloy thin film 12 that has undergone the thin film depositing step S400 exhibited an amorphous state.

However, completion of crystallization can be seen after the crystallizing step S500 is performed at 500° C. for 30 minutes, as in FIG. 15.

However, when the annealing temperature was 400° C. and 450° C. under 500° C. in the crystallizing step S500, as in FIGS. 13 and 14, complete crystallization was not achieved even under the same annealing time.

Accordingly, it is preferable that the crystallizing step S500 is performed at 500° C. or more for 30 minutes or more.

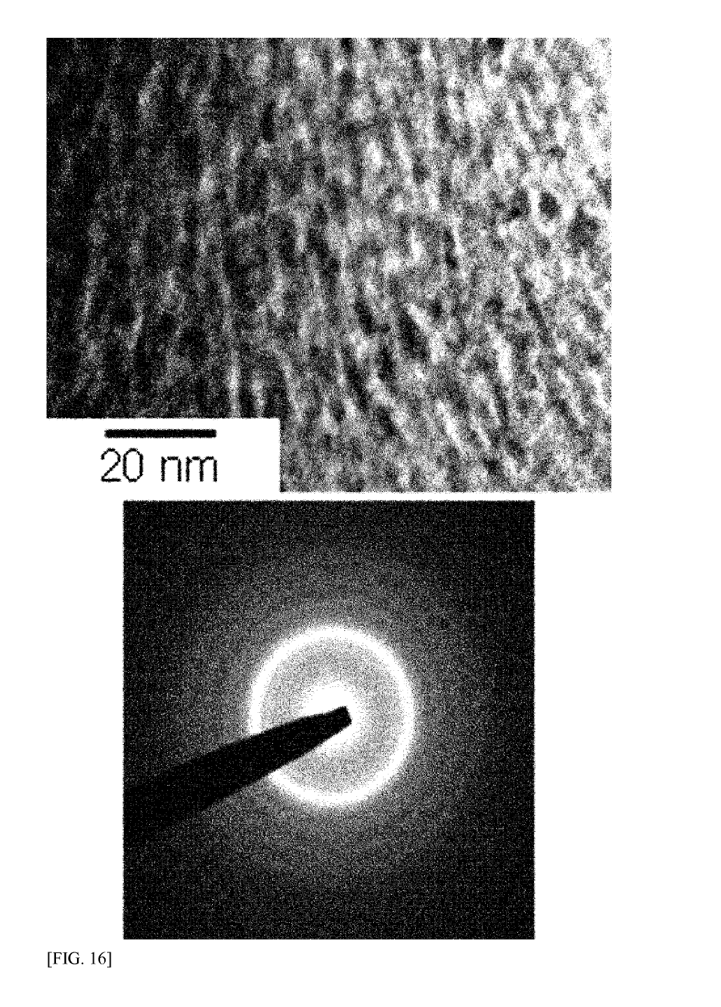

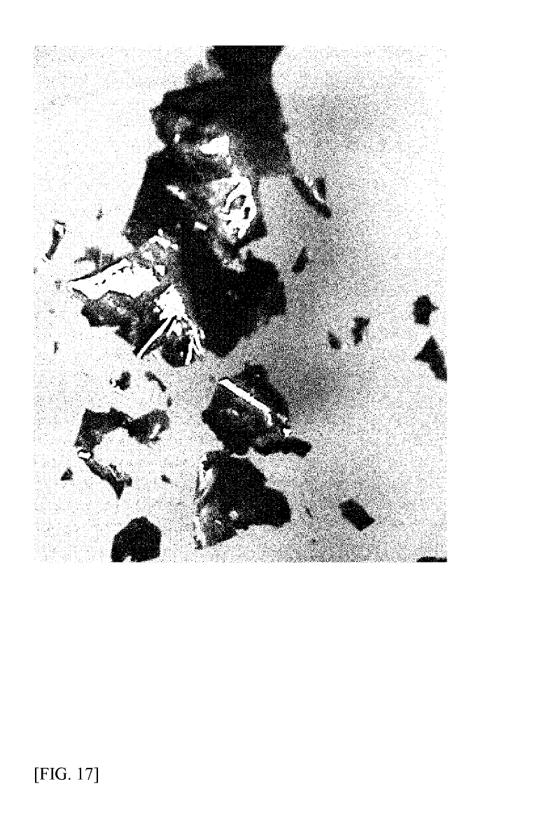

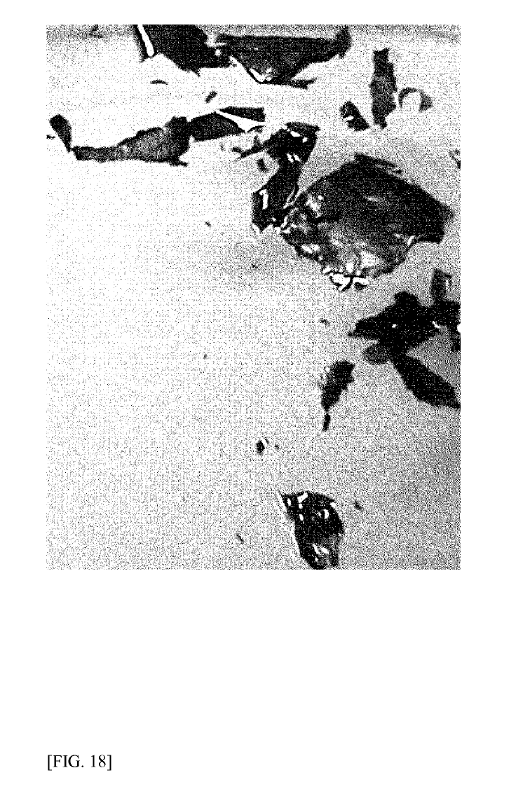

FIGS. 16 and 17 exhibit a Ti—Ni ally thin film 12 fabricated for annealing time of one hour and ten hours with the annealing temperature maintained at 500° C. in the crystallizing step S500, in which it can be seen that the Ti—Ni alloy thin film 12 keeps the shape without deforming after the annealing.

Further, compared with the embodiment of FIGS. 16 and 17, the Ti—Ni alloy thin film 12 was not deformed when the crystallizing step S500 was performed at 1000° C. for one hour even in FIG. 18 in which the content of Ti was increased.

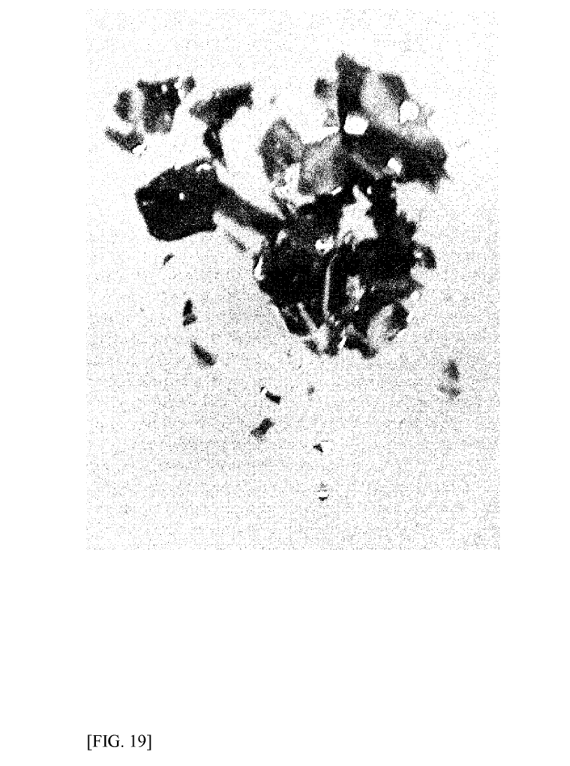

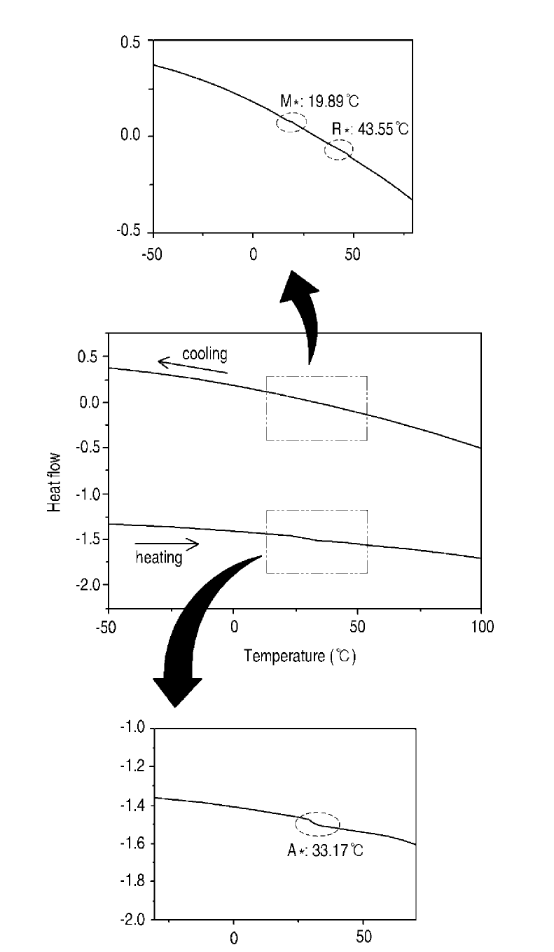

FIG. 19 is an actual picture and a table listing a thermal flow result according to a temperature change in a preferred embodiment 60 in the method of fabricating a Ti—Ni alloy thin film using co-sputtering, in which the Ti—Ni alloy thin film 12 has undergone water quenching (function applying step (S600)) after the crystallizing step S500 was performed at 500° C. for one hour.

As in the picture, the Ti—Ni alloy thin film 12 exhibited an A* transformation temperature at about 33.17 degrees in heating and exhibited 43.55 degrees (R transformation) and 19.89 degrees (M transformation) in cooling.

The size of the peak was relatively small because the amount of the sample of the thin film is small, but it was enough for checking the transformation point. It was seen that the thin film given functions through annealing exhibited a shape memory effect, as the result of measuring thermal flow.

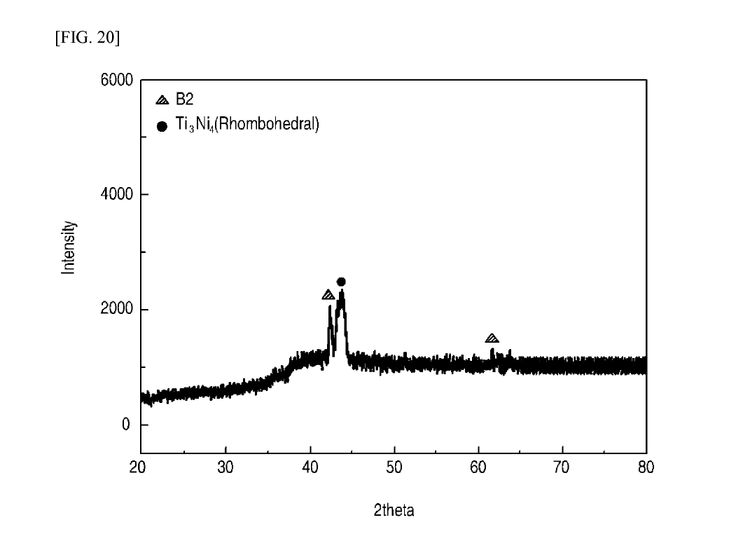

Further, it was seen that the Ti—Ni alloy thin film 12 includes B₂ and Rhombohedral (Ti₃Ni₄) phases having a shape memory function, as in FIG. 20, after the function applying step (S600) is performed.

The scope of the present invention is not limited to the embodiments described above and many other modifications based on the present invention may be achieved by those skilled in the art within the scope of the present invention.

### INDUSTRIAL APPLICABILITY

The present invention fabricates a Ti—Ni alloy thin film by putting a Ti target and an Ni target separately prepared at a predetermined distance from each other in the chamber and then simultaneously sputtering them under different conditions.

Accordingly, it is possible to set the composition ratio of Ti and Ni to be optimum in accordance with characteristics required for the Ti—Ni alloy thin film, such that the present invention can be widely used for various fields.

Further, when NaCl is selected as a base material, the fabricating process of a Ti—Ni alloy thin film is simplified and the fabricating cost can be reduced.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A Ti—Ni alloy thin film with Ti and Ni mixed and deposited on a base material, the Ti—Ni alloy thin film being prepared by putting a Ti target and a Ni target at a predetermined distance from each other in a co-sputtering apparatus and simultaneously sputtering the targets by applying different voltages.

2. A Ti—Ni alloy thin film with Ti and Ni mixed and deposited on a base material, the Ti—Ni alloy thin film being prepared by putting a Ti target and an Ni target at a predetermined distance from each other in a co-sputtering apparatus and simultaneously sputtering the targets by applying different voltages, wherein the Ti—Ni alloy thin film is crystallized by annealing at 500° C. or more for 30 minutes or more.

3. The Ti—Ni alloy thin film of claim 1, wherein the base material is made of any one of Si wafer, monocrystal NaCl, and polycrystalline NaCl.

4. The Ti—Ni alloy thin film of claim 3, wherein the Ti of 43.2 to 44.9 wt % to the entire weight of the Ti—Ni alloy thin film is included.

5. The Ti—Ni alloy thin film of claim 4, wherein a voltage 3.2 to 3.4 times higher than that of the Ni target is applied to the Ti target.

6. The Ti—Ni alloy thin film of claim 2, wherein the Ti—Ni alloy thin film includes B₂ Rhombohedral (Ti₃Ni₄) in rapid cooling after annealing.

7. A method of fabricating a Ti—Ni alloy thin film using co-sputtering, the method comprising:
a target preparing step that prepares a Ti target, a Ni target, and a base material;
a target disposing step that puts the Ti target and the Ni target at a predetermined distance from each other in a co-sputtering apparatus;
an apparatus setting step that sets work conditions of the co-sputtering apparatus; and
a thin film depositing step that forms a Ti—Ni alloy thin film with Ti and Ni mixed on the base material by operating the co-sputtering apparatus.

8. A method of fabricating a Ti—Ni alloy thin film using co-sputtering, the method comprising:
a target preparing step that prepares a Ti target, a Ni target, and a base material;
a target disposing step that puts the Ti target and the Ni target at a predetermined distance from each other in a co-sputtering apparatus;
an apparatus setting step that sets work conditions of the co-sputtering apparatus;
a thin film depositing step that forms a Ti—Ni alloy thin film with Ti and Ni mixed on the base material by operating the co-sputtering apparatus;
a crystallizing step that crystallizes the Ti—Ni alloy thin film by annealing the Ti—Ni alloy thin film at a temperature of 500° C. or more for 30 minutes or more; and
a function applying step that forms B₂ and Rhombohedral (Ti₃Ni₄) phases by rapidly cooling the crystallized Ti—Ni alloy thin film.

9. The method of claim 7, wherein in the target preparing step, the base material is selected from any one of Si wafer, monocrystal NaCl, and polycrystalline NaCl.

10. The method of claim 9, wherein after the thin film depositing step, a thin film separating step that removes the base material is performed when the base material is made of monocrystal NaCl.

11. The method of claim 10, wherein in the apparatus setting step, a voltage 3.2 to 3.4 times higher than that of the Ni target is applied to the Ti target.

12. The method of claim 11, wherein in the thin film depositing step, Ti has an atomic ratio of 48.53 to 54.33 to the entire Ti—Ni alloy thin film.

13. The Ti—Ni alloy thin film of claim 2, wherein the base material is made of any one of Si wafer, monocrystal NaCl, and polycrystalline NaCl.

14. The Ti—Ni alloy thin film of claim 13, wherein the Ti of 43.2 to 44.9 wt % to the entire weight of the Ti—Ni alloy thin film is included.

15. The Ti—Ni alloy thin film of claim 14, wherein a voltage 3.2 to 3.4 times higher than that of the Ni target is applied to the Ti target.

16. The method of claim 8, wherein in the target preparing step, the base material is selected from any one of Si wafer, monocrystal NaCl, and polycrystalline NaCl.

17. The method of claim 16, wherein after the thin film depositing step, a thin film separating step that removes the base material is performed when the base material is made of monocrystal NaCl.

18. The method of claim 17, wherein in the apparatus setting step, a voltage 3.2 to 3.4 times higher than that of the Ni target is applied to the Ti target.

19. The method of claim 18, wherein in the thin film depositing step, Ti has an atomic ratio of 48.53 to 54.33 to the entire Ti—Ni alloy thin film.
